(19) United States
(12) Patent Application Publication
(10) Pub. No.: US 2026/0276707 A1
(43) Pub. Date: Sep. 17, 2026

(54) FAULT DETECTION

(71) Applicant: Arm Limited, Cambridge (GB)

(72) Inventors: Luca SCALABRINO, Le Rouret (FR); Frederic Jean Denis ARSANTO, Le Rouret (FR)

(21) Appl. No.: 19/075,985

(22) Filed: Mar. 11, 2025

(51) Int. Cl. G01R 31/3185

(52) U.S. Cl. CPC G01R 31/318525

(57) ABSTRACT

Data processing circuitry has data flip-flop parity circuitry comprising: prior parity calculation circuitry positioned prior to a data flip-flop group, post parity calculation circuitry positioned following the data flip-flop group; and parity comparison circuitry to compare respective outputs from the prior and post parity calculation circuitries. A parity fault is signalled when the respective outputs differ. Parity value capturing circuitry extracts a parity value from a node in the data flip-flop parity circuitry positioned before the parity comparison circuitry. Characteristic parity value storage stores a characteristic parity value in dependence on the parity value extracted from the node by the parity value capturing circuitry.

### TECHNICAL FIELD

The present disclosure relates to data processing. In particular, the present disclosure relates to identifying when faults occur in a data processing apparatus.

### DESCRIPTION

In addition to the circuitry forming part of a data processing apparatus that performs the data processing, further components may be added in order to verify the integrity of certain aspects of that data processing. For example, single transient faults occurring in data flip-flops can be identified by the use of parity value comparisons.

### SUMMARY

In one example described herein there is an apparatus comprising: data processing circuitry comprising data flip-flop parity circuitry, wherein the data flip-flop parity circuitry comprises: prior parity calculation circuitry positioned prior to a data flip-flop group; post parity calculation circuitry positioned following the data flip-flop group; and parity comparison circuitry configured to compare respective outputs from the prior parity calculation circuitry and the post parity calculation circuitry, wherein the parity comparison circuitry is configured to signal a parity fault when the respective outputs differ; parity value capturing circuitry configured to extract a parity value from a node in the data flip-flop parity circuitry, wherein the node is positioned before the parity comparison circuitry; and characteristic parity value storage configured to store a characteristic parity value in dependence on the parity value extracted from the node by the parity value capturing circuitry.

In one example described herein there is a method of operating the apparatus of any described example comprising: executing software to perform integrity verification of the apparatus, wherein the integrity verification comprises comparing the characteristic parity value stored in the characteristic parity value storage with a predetermined parity value at a predetermined time-point in operation of the apparatus.

In one example described herein there is a system comprising: the apparatus of any described example, implemented in at least one packaged chip; at least one system component; and a board, wherein the at least one packaged chip and the at least one system component are assembled on the board.

In one example described herein there is a chip-containing product comprising the system of any described example, wherein the system is assembled on a further board with at least one other product component.

### BRIEF DESCRIPTION OF THE DRAWINGS

The present invention will be described further, by way of example only, with reference to embodiments thereof as illustrated in the accompanying drawings, in which:

FIG. 1 schematically illustrates circuitry comprising data flip-flops in accordance with some examples;

FIG. 2 schematically illustrates circuitry comprising data flip-flops and combinatorial circuitry in accordance with some examples;

FIG. 3 schematically illustrates a set of modules in an apparatus in accordance with some examples;

FIG. 4 is a flow diagram showing a sequence of steps that are taken in accordance with some examples;

FIG. 5 is a flow diagram showing a sequence of steps that are taken in accordance with some examples;

FIG. 6 is a flow diagram showing a sequence of steps that are taken in accordance with some examples; and

FIG. 7 schematically illustrates a chip-containing product, a system assembled on a board, and an assembly on a further board in accordance with some examples.

### DESCRIPTION OF EXAMPLE EMBODIMENTS

Before discussing the embodiments with reference to the accompanying figures, the following description of embodiments is provided.

In accordance with example configurations there is provided an apparatus comprising: data processing circuitry comprising data flip-flop parity circuitry, wherein the data flip-flop parity circuitry comprises: prior parity calculation circuitry positioned prior to a data flip-flop group; post parity calculation circuitry positioned following the data flip-flop group; and parity comparison circuitry configured to compare respective outputs from the prior parity calculation circuitry and the post parity calculation circuitry, wherein the parity comparison circuitry is configured to signal a parity fault when the respective outputs differ; parity value capturing circuitry configured to extract a parity value from a node in the data flip-flop parity circuitry, wherein the node is positioned before the parity comparison circuitry; and characteristic parity value storage configured to store a characteristic parity value in dependence on the parity value extracted from the node by the parity value capturing circuitry.

The inventors have recognised that whilst a parity calculation may be performed before and after a data flip-flop group, in order to compare the outputs of those respective parity calculations and to signal a parity fault when the two differ, this is not possible with combinatorial circuitry (where typically one data flip-flop group feeds inputs to combinatorial circuitry and another data flip-flop group captures the outputs of the combinatorial circuitry), since there is no reason for the parity of inputs to combinatorial circuitry to be indicative of the parity of outputs from the combinatorial circuitry. Nevertheless, the inventors have further realised that monitoring the integrity of combinatorial logic, in particular for the occurrence of permanent errors, can be supported through the determination of such parity values. In the context of circuitry in which transient parity protection is provided to monitor the integrity of a data flip-flop group (by comparing a parity value calculated before and after the data flip-flop group), the present techniques add parity value capturing circuitry that is configured to extract a parity value from a point prior to the parity comparison circuitry, whereby a characteristic parity value that depends on the parity value extracted is caused to be stored to characteristic parity value storage. This extracted and stored parity value is then characteristic of the point in the apparatus from which it was taken, and allows a snapshot of the state of the apparatus to be captured at relevant timepoints (e.g. after reset or on a specific event) or under certain conditions (e.g. execution of a particular instruction). The time evolution of such a snapshot may also be captured and studied.

In some examples, the data processing circuitry comprises multiple data flip-flop parity circuitries, wherein the parity value capturing circuitry is configured to extract respective parity values from respective nodes in the multiple data flip-flop parity circuitries, and wherein the parity value capturing circuitry is configured to generate the characteristic parity value in dependence on a combination of the respective parity values. Accordingly, the respective parity values can be combined either directly giving the characteristic parity value or giving an intermediate value on which the characteristic value is based.

The respective parity values may be combined in a variety of ways, but in some examples the parity value capturing circuitry is configured to generate the characteristic parity value as a summation of the respective parity values.

As outlined above, the present techniques may be used to monitor the integrity of data combinatorial circuitry, and in some examples the data processing circuitry further comprises data combinatorial circuitry, wherein the data combinatorial circuitry is configured to perform multiple data combination operations asynchronously with respect to the data flip-flop group, and wherein the data flip-flop parity circuitry is positioned at an output of the data combinatorial circuitry. This allows the extracted parity value and hence the characteristic parity value to be indicative of the state of the data combinatorial circuitry, such that the occurrence of a permanent fault can be monitored.

The capturing of a characteristic parity value indicative of the state of a certain portion of circuitry in the apparatus may be configured to be associated with defined sections or modules of the apparatus, such that a set of characteristic parity values is then representative of the state of a range of sections of the apparatus. In some examples, the data processing circuitry comprises multiple modules, wherein each module has a defined functional role in the apparatus, and the data processing circuitry comprises multiple parity value capturing circuitries, wherein each of the multiple parity value capturing circuitries is associated with a respective module of the multiple modules, and wherein the respective parity value capturing circuitries are configured to generate a respective characteristic parity value associated with their associated module.

The characteristic parity value storage may take a variety of forms. In some examples, the characteristic parity value storage is a software accessible register of the apparatus. This facilitates the access to and study of the stored characteristic parity value(s).

The extracted parity value may be taken from various positions (or “nodes”) in the apparatus, but in some examples the node is positioned after the prior parity calculation circuitry and before the parity comparison circuitry. In other examples the node is positioned after the post parity calculation circuitry and before the parity comparison circuitry. Depending on the implementation one of these configurations may be preferred over the other, e.g. for timing reasons.

In accordance with one example configuration there is provided a method of operating the apparatus of any of the above examples comprising: executing software to perform integrity verification of the apparatus, wherein the integrity verification comprises comparing the characteristic parity value stored in the characteristic parity value storage with a predetermined parity value at a predetermined time-point in operation of the apparatus.

In some examples, the method further comprises signalling compromised integrity when the characteristic parity value differs from the predetermined parity value.

In some examples of the method, the predetermined time-point is immediately following a reset of the apparatus. In some examples, the predetermined time-point is at a predetermined processing point during operation of the apparatus.

In some examples of the method, the integrity verification comprises comparing an evolution sequence of the characteristic parity value stored in the characteristic parity value storage with a predetermined evolution sequence of the predetermined parity value.

In some examples of the method, the integrity verification comprises determining whether the characteristic parity value stored in the characteristic parity value storage represents an impossible value, wherein prior analysis of the apparatus has determined that the characteristic parity value cannot attain the impossible value during correct operation of the apparatus.

In some examples, the method further comprises performing, prior to executing the software to perform integrity verification of the apparatus, a formal verification procedure to determine at least one of: at least one possible value for the characteristic parity value; and/or at least one impossible value for the characteristic parity value.

In accordance with example configurations there is provided a system comprising: the apparatus of any of the above examples, implemented in at least one packaged chip; at least one system component; and a board, wherein the at least one packaged chip and the at least one system component are assembled on the board.

In accordance with example configurations there is provided a chip-containing product comprising the system of any of the above examples, wherein the system is assembled on a further board with at least one other product component.

Particular embodiments will now be described with reference to the figures.

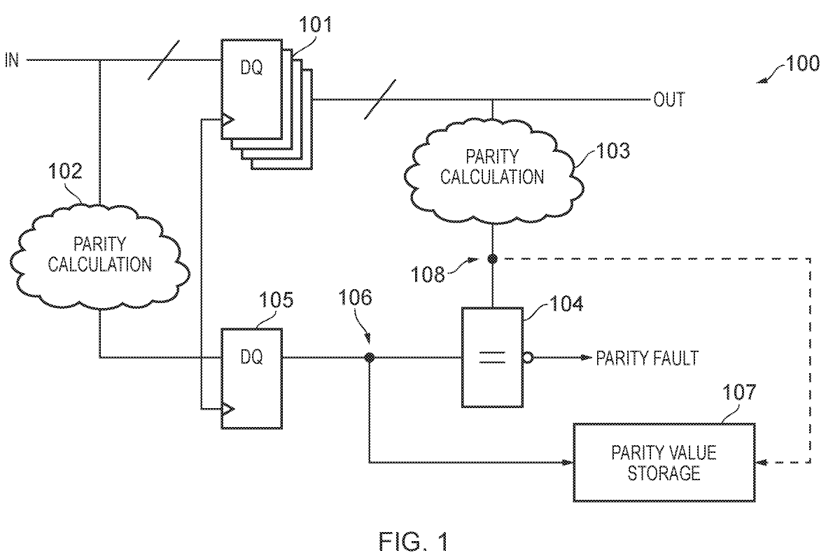

FIG. 1 illustrates an apparatus 100 in accordance with one embodiment. The apparatus 100 comprises a data flip-flop group 101 that has a multi-bit input and a multi-bit output. Such a data flip-flop group may for example be provided in a data processing apparatus to receive the output of a first set of combinatorial circuitry, temporarily holding that set of data values before providing the input to a second set of combinatorial circuitry. In order to monitor the integrity of the data flip-flop group 101 there is also provided data flip-flop parity circuitry comprising parity calculation circuitry 102 and parity calculation circuitry 103. The parity calculation circuitry 102 determines a parity value based on the inputs to the data flip-flop group 101 and the parity calculation circuitry 103 determines a parity value based on the output of the data flip-flop group 101. The data flip-flop parity circuitry also comprises parity comparison circuitry 104, which is configured to compare the respective outputs from the parity calculation circuitry 102 and the parity calculation circuitry 103. When these respective outputs differ, the parity comparison circuitry 104 signals a parity fault. The data flip-flop parity circuitry also comprises a further data flip-flop 105 that is synchronous with the data flip-flop group 101. This data flip-flop receives the parity value output by the parity calculation circuitry 102 and provides this value as one of the inputs to the parity comparison circuitry 104. The apparatus is further configured to extract a parity value from a position (a node) prior to the parity comparison circuitry 104. In the illustrated example, this node 106 is shown to be on the path from the parity calculation circuitry 102 and the data flip-flop 105 leading to the parity comparison circuitry 104. The value from this node is taken and stored in the parity value storage 107. The node and the path to the parity value storage 107 thus represent an example of parity value capturing circuitry. A characteristic parity value stored in the parity value storage may be directly the same as the parity value extracted from the node by the parity value capturing circuitry, or may be dependent thereon. An alternative node 108 is also shown in the figure from which the parity value might be extracted for storage in the parity value storage 107. The parity value storage 107 may be one or more software accessible registers provided in the apparatus, such that the characteristic parity value(s) stored therein can be accessed and analysed (e.g. by software test libraries).

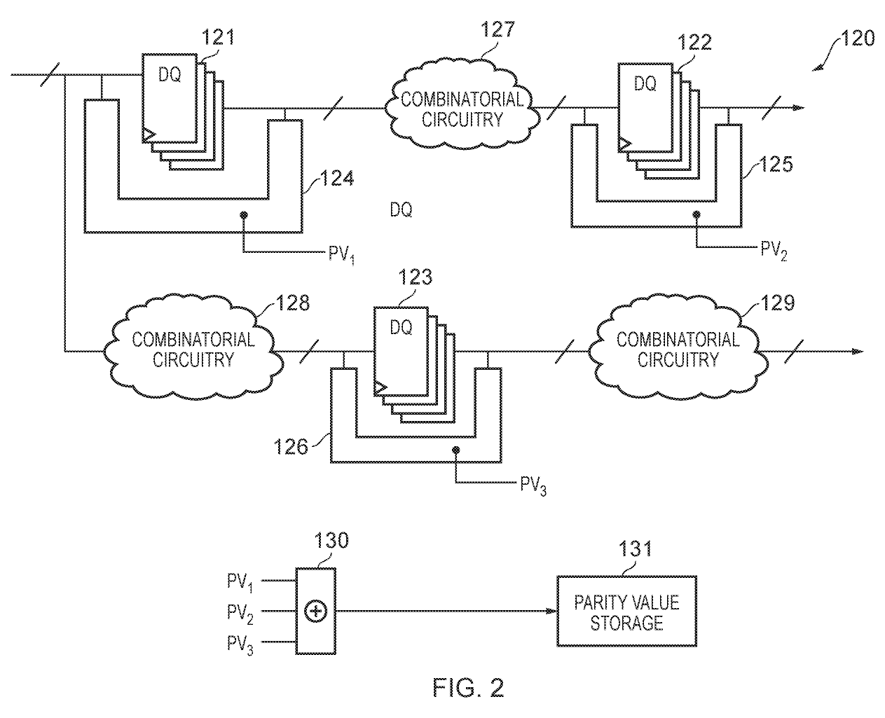

FIG. 2 illustrates an apparatus 120 in accordance with one embodiment. The apparatus 120 comprises a number of data flip-flop groups 121, 122, 123 that each has a multi-bit input and a multi-bit output. The data flip-flop groups 121, 122, 123 are provided for synchronisation purposes receiving their multi-bit inputs from combinatorial circuitry and providing their multi-bit outputs to combinatorial circuitry. Three examples of combinatorial circuitry 127, 128, 129 are shown in the example of FIG. 2. Each data flip-flop groups 121, 122, 123 has associated data flip-flop parity circuitry 124, 125, 126 respectively, whereby the data flip-flop parity circuitry is provided in order to monitor the integrity of the respective data flip-flop group (as described above with reference to FIG. 1). A parity value is extracted from each data flip-flop parity circuitry 124, 125, 126 respectively, indicated in the figure as PV₁, PV₂, and PV₃ respectively. These respective parity values are combined by combination circuitry 130, which in the example of FIG. 2 sums their values but could combine them in any other arithmetically or logically feasible manner. The combined value provides a characteristic parity value that is stored in the parity value storage 131.

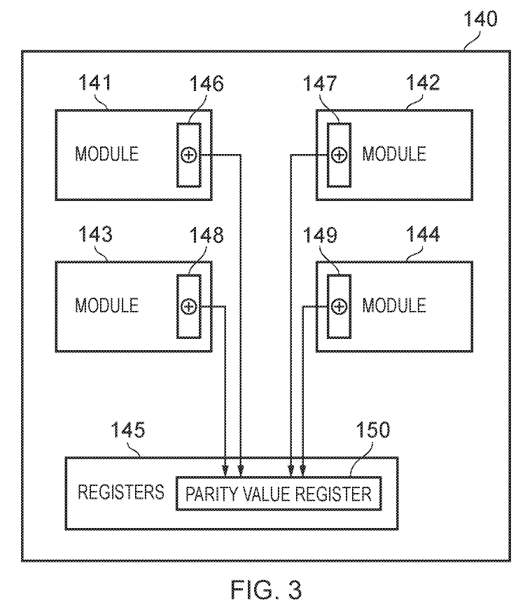

FIG. 3 illustrates an apparatus 140 in accordance with one embodiment. The apparatus 140 comprises a number of modules 141, 142, 143, 144 that each may comprises any number of data flip-flop groups and sets of combinatorial circuitry (see FIG. 2). The modules generally correspond to different functional units within the apparatus. Each module comprises combination circuitry 146, 147, 148, 149 configured (as described with reference to the example of FIG. 2) to combine multiple parity values extracted from respective sets of data flip-flop parity circuitry within that module. There may be any arbitrary number of inputs to the combination circuitry 146, 147, 148, 149. The output of each combination circuitry 146, 147, 148, 149 thus provides a characteristic parity value representative of the state of that module. These characteristic parity values are individually stored in a parity value register 150 within a set of registers 145 in the apparatus 140. These characteristic parity values may then later be accessed by software to determine an integrity status of the apparatus.

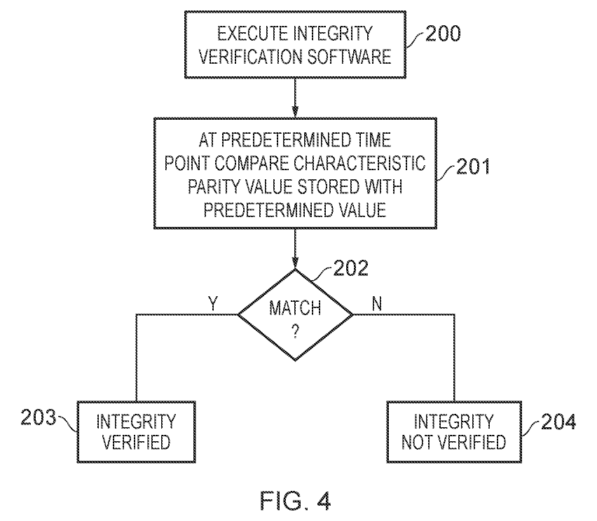

FIG. 4 shows a sequence of steps that are carried out in accordance with the method of one embodiment, for example by software that is run in order to determine an integrity status of the apparatus as mentioned above. Execution of integrity verification software starts the sequence at step 200. Then, at step 201 at a predetermined time point a characteristic parity value retrieved from characteristic parity value storage (e.g. the parity value register 150) is compared with a predetermined value. For example, the predetermined time point may be immediately following a reset of the apparatus. The predetermined value against which the retrieved characteristic parity value is compared in such an example can thus be a known (expected) reset state. The predetermined time point could also be tied to other events or actions (e.g. instruction execution). If the values match (step 202) then at step 203 the integrity of the apparatus has been verified. Otherwise (step 204) the integrity of the apparatus has not been verified (and suitable error messages or remedial action may be triggered).

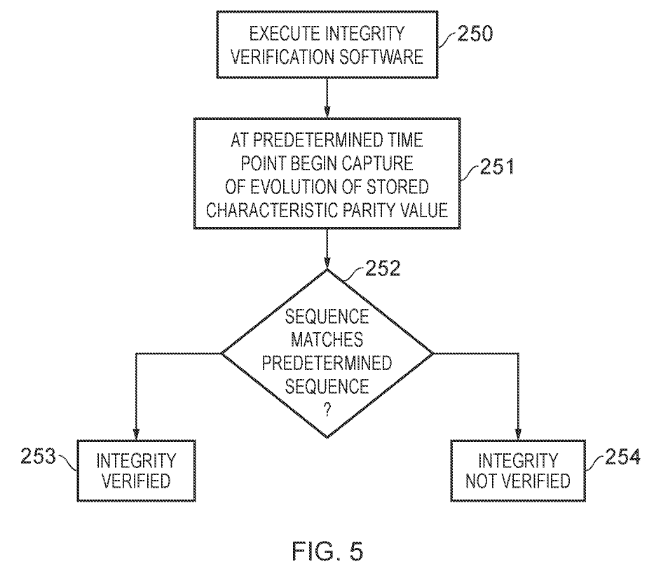

FIG. 5 shows a sequence of steps that are carried out in accordance with the method of one embodiment, for example by software that is run in order to determine an integrity status of the apparatus as mentioned above. Execution of integrity verification software starts the sequence at step 250. Then, at step 251 at a predetermined time point a capture process is started to capture the time evolution of the stored characteristic parity value, i.e. the value may for example be retrieved at set time intervals over a period from the characteristic parity value storage (e.g. the parity value register 150). This sequence of values is then compared (step 252) with a predetermined sequence of values. Again, the predetermined time point may be immediately following a reset of the apparatus, or may be initiated by other events or actions (e.g. instruction execution). If the values match then at step 253 the integrity of the apparatus has been verified. Otherwise (step 254) the integrity of the apparatus has not been verified (and suitable error messages or remedial action may be triggered).

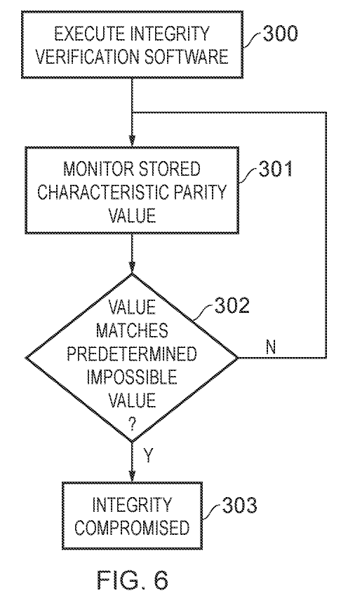

The present techniques further recognise that the characteristic parity value stored, e.g. in a parity value register, may only be able to take certain values. That is, for a correctly functioning apparatus, there may be certain values that are impossible to arise, due to the configuration of respective parts of the apparatus and their interactions. Integrity verification of the apparatus can therefore comprise determining whether a given characteristic parity value stored is a possible or an impossible value. An example method carrying out this type of check is shown in FIG. 6, which shows a sequence of steps that are carried out in accordance with the method of one embodiment, for example by software that is run in order to determine an integrity status of the apparatus as mentioned above. Execution of integrity verification software starts the sequence at step 300. Then, at step 301 monitoring of the stored characteristic parity value begins. It is determined at step 302 whether the current value is impossible or not. When it is not, the flow continues, looping back to step 301. However when an impossible value is identified, at step 303 the integrity of the apparatus has been found to be compromised. This may then trigger suitable error messages or remedial actions.

Concepts described herein may be embodied in a system comprising at least one packaged chip. The apparatus described earlier is implemented in the at least one packaged chip (either being implemented in one specific chip of the system, or distributed over more than one packaged chip). The at least one packaged chip is assembled on a board with at least one system component. A chip-containing product may comprise the system assembled on a further board with at least one other product component. The system or the chip-containing product may be assembled into a housing or onto a structural support (such as a frame or blade).

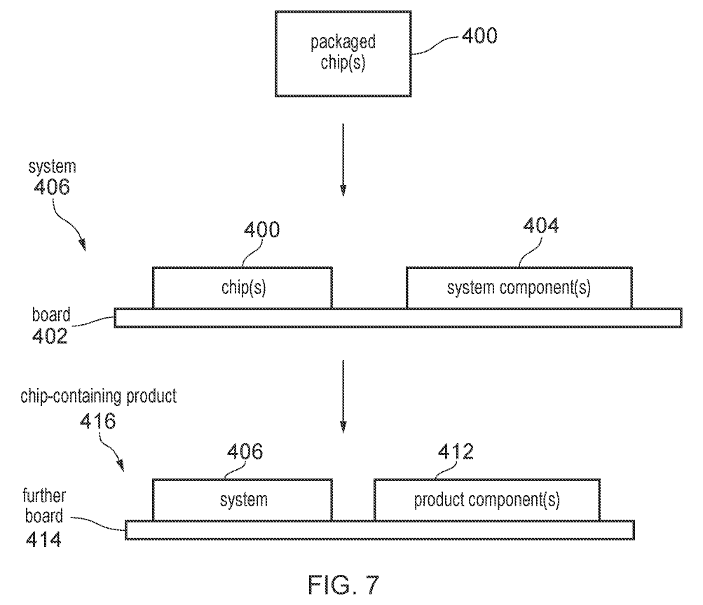

As shown in FIG. 7, one or more packaged chips 400, with the apparatus described above implemented on one chip or distributed over two or more of the chips, are manufactured by a semiconductor chip manufacturer. In some examples, the chip product 400 made by the semiconductor chip manufacturer may be provided as a semiconductor package which comprises a protective casing (e.g. made of metal, plastic, glass or ceramic) containing the semiconductor devices implementing the apparatus described above and connectors, such as lands, balls or pins, for connecting the semiconductor devices to an external environment. Where more than one chip 400 is provided, these could be provided as separate integrated circuits (provided as separate packages), or could be packaged by the semiconductor provider into a multi-chip semiconductor package (e.g. using an interposer, or by using three-dimensional integration to provide a multi-layer chip product comprising two or more vertically stacked integrated circuit layers).

In some examples, a collection of chiplets (i.e. small modular chips with particular functionality) may itself be referred to as a chip. A chiplet may be packaged individually in a semiconductor package and/or together with other chiplets into a multi-chiplet semiconductor package (e.g. using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g. plastic, glass, ceramic, or a flexible substrate material such as paper, plastic or textile material. The at least one system component 404 comprise one or more external components which are not part of the one or more packaged chip(s) 400. For example, the at least one system component 404 could include, for example, any one or more of the following: another packaged chip (e.g. provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components that are not part of the system 406. As a non-exhaustive list of examples, the one or more product components 412 could include a user input/output device such as a keypad, touch screen, microphone, loudspeaker, display screen, haptic device, etc.; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g. a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g. a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions that are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Various example configurations are set out in the following numbered clauses:

Clause 1. Apparatus comprising:
data processing circuitry comprising data flip-flop parity circuitry, wherein the data flip-flop parity circuitry comprises:
   prior parity calculation circuitry positioned prior to a data flip-flop group;
   post parity calculation circuitry positioned following the data flip-flop group; and
   parity comparison circuitry configured to compare respective outputs from the prior parity calculation circuitry and the post parity calculation circuitry, wherein the parity comparison circuitry is configured to signal a parity fault when the respective outputs differ;
parity value capturing circuitry configured to extract a parity value from a node in the data flip-flop parity circuitry, wherein the node is positioned before the parity comparison circuitry; and
characteristic parity value storage configured to store a characteristic parity value in dependence on the parity value extracted from the node by the parity value capturing circuitry.

Clause 2. The apparatus of Clause 1, wherein the data processing circuitry comprises multiple data flip-flop parity circuitries,
wherein the parity value capturing circuitry is configured to extract respective parity values from respective nodes in the multiple data flip-flop parity circuitries,
and wherein the parity value capturing circuitry is configured to generate the characteristic parity value in dependence on a combination of the respective parity values.

Clause 3. The apparatus of Clause 2, wherein the parity value capturing circuitry is configured to generate the characteristic parity value as a summation of the respective parity values.

Clause 4. The apparatus of any of Clauses 1-3, wherein the data processing circuitry further comprises data combinatorial circuitry,
wherein the data combinatorial circuitry is configured to perform multiple data combination operations asynchronously with respect to the data flip-flop group,
and wherein the data flip-flop parity circuitry is positioned at an output of the data combinatorial circuitry.

Clause 5. The apparatus of Clause 2 or Clause 3, wherein the data processing circuitry comprises multiple modules, wherein each module has a defined functional role in the apparatus, and
the data processing circuitry comprises multiple parity value capturing circuitries, wherein each of the multiple parity value capturing circuitries is associated with a respective module of the multiple modules,
and wherein the respective parity value capturing circuitries are configured to generate a respective characteristic parity value associated with their associated module.

Clause 6. The apparatus of any of Clauses 1-5, wherein the characteristic parity value storage is a software accessible register of the apparatus.

Clause 7. The apparatus of Clause 1, wherein the node is positioned after the prior parity calculation circuitry and before the parity comparison circuitry.

Clause 8. The apparatus of Clause 1, wherein the node is positioned after the post parity calculation circuitry and before the parity comparison circuitry .

Clause 9. A method of operating the apparatus of any of Clauses 1-8 comprising:
executing software to perform integrity verification of the apparatus,
wherein the integrity verification comprises comparing the characteristic parity value stored in the characteristic parity value storage with a predetermined parity value at a predetermined time-point in operation of the apparatus.

Clause 10. The method of Clause 9, further comprising signalling compromised integrity when the characteristic parity value differs from the predetermined parity value.

Clause 11. The method of Clause 9 or Clause 10, wherein the predetermined time-point is immediately following a reset of the apparatus.

Clause 12. The method of Clause 9 or Clause 10, wherein the predetermined time-point is at a predetermined processing point during operation of the apparatus.

Clause 13. The method of any of Clauses 9-12, wherein the integrity verification comprises comparing an evolution sequence of the characteristic parity value stored in the characteristic parity value storage with a predetermined evolution sequence of the predetermined parity value.

Clause 14. The method of any of Clauses 9-13, wherein the integrity verification comprises determining whether the characteristic parity value stored in the characteristic parity value storage represents an impossible value,

wherein prior analysis of the apparatus has determined that the characteristic parity value cannot attain the impossible value during correct operation of the apparatus.

Clause 15. The method of any of Clauses 9-14, further comprising performing, prior to executing the software to perform integrity verification of the apparatus, a formal verification procedure to determine at least one of:
at least one possible value for the characteristic parity value; and/or
at least one impossible value for the characteristic parity value.

Clause 16. A system comprising:
the apparatus of any of Clauses 1-8, implemented in at least one packaged chip;
at least one system component; and
a board,
wherein the at least one packaged chip and the at least one system component are assembled on the board.

Clause 17. A chip-containing product comprising the system of Clause 16, wherein the system is assembled on a further board with at least one other product component.

Clause 18. A non-transitory computer-readable medium storing computer-readable code for fabrication of an apparatus comprising:
data processing circuitry comprising data flip-flop parity circuitry, wherein the data flip-flop parity circuitry comprises:
   prior parity calculation circuitry positioned prior to a data flip-flop group;
   post parity calculation circuitry positioned following the data flip-flop group; and
   parity comparison circuitry configured to compare respective outputs from the prior parity calculation circuitry and the post parity calculation circuitry, wherein the parity comparison circuitry is configured to signal a parity fault when the respective outputs differ;
parity value capturing circuitry configured to extract a parity value from a node in the data flip-flop parity circuitry, wherein the node is positioned before the parity comparison circuitry; and
characteristic parity value storage configured to store a characteristic parity value in dependence on the parity value extracted from the node by the parity value capturing circuitry.

In brief overall summary data processing circuitry has data flip-flop parity circuitry comprising: prior parity calculation circuitry positioned prior to a data flip-flop group, post parity calculation circuitry positioned following the data flip-flop group; and parity comparison circuitry to compare respective outputs from the prior and post parity calculation circuitries. A parity fault is signalled when the respective outputs differ. Parity value capturing circuitry extracts a parity value from a node in the data flip-flop parity circuitry positioned before the parity comparison circuitry. Characteristic parity value storage stores a characteristic parity value in dependence on the parity value extracted from the node by the parity value capturing circuitry.

In the present application, the words “configured to…” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

Although illustrative embodiments of the invention have been described in detail herein with reference to the accompanying drawings, it is to be understood that the invention is not limited to those precise embodiments, and that various changes, additions and modifications can be effected therein by one skilled in the art without departing from the scope of the invention as defined by the appended Clauses. For example, various combinations of the features of the dependent Clauses could be made with the features of the independent Clauses without departing from the scope of the present invention.

We claim:

1. Apparatus comprising:
data processing circuitry comprising data flip-flop parity circuitry, wherein the data flip-flop parity circuitry comprises:
prior parity calculation circuitry positioned prior to a data flip-flop group;
post parity calculation circuitry positioned following the data flip-flop group; and
parity comparison circuitry configured to compare respective outputs from the prior parity calculation circuitry and the post parity calculation circuitry, wherein the parity comparison circuitry is configured to signal a parity fault when the respective outputs differ;
parity value capturing circuitry configured to extract a parity value from a node in the data flip-flop parity circuitry, wherein the node is positioned before the parity comparison circuitry; and
characteristic parity value storage configured to store a characteristic parity value in dependence on the parity value extracted from the node by the parity value capturing circuitry.

2. The apparatus of claim 1, wherein the data processing circuitry comprises multiple data flip-flop parity circuitries,
wherein the parity value capturing circuitry is configured to extract respective parity values from respective nodes in the multiple data flip-flop parity circuitries,
and wherein the parity value capturing circuitry is configured to generate the characteristic parity value in dependence on a combination of the respective parity values.

3. The apparatus of claim 2, wherein the parity value capturing circuitry is configured to generate the characteristic parity value as a summation of the respective parity values.

4. The apparatus of claim 1, wherein the data processing circuitry further comprises data combinatorial circuitry,
wherein the data combinatorial circuitry is configured to perform multiple data combination operations asynchronously with respect to the data flip-flop group,
and wherein the data flip-flop parity circuitry is positioned at an output of the data combinatorial circuitry.

5. The apparatus of claim 2, wherein the data processing circuitry comprises multiple modules, wherein each module has a defined functional role in the apparatus, and
the data processing circuitry comprises multiple parity value capturing circuitries, wherein each of the multiple parity value capturing circuitries is associated with a respective module of the multiple modules,
and wherein the respective parity value capturing circuitries are configured to generate a respective characteristic parity value associated with their associated module.

6. The apparatus of claim 1, wherein the characteristic parity value storage is a software accessible register of the apparatus.

7. The apparatus of claim 1, wherein the node is positioned after the prior parity calculation circuitry and before the parity comparison circuitry.

8. The apparatus of claim 1, wherein the node is positioned after the post parity calculation circuitry and before the parity comparison circuitry.

9. A method of operating the apparatus of claim 1 comprising:
executing software to perform integrity verification of the apparatus,
wherein the integrity verification comprises comparing the characteristic parity value stored in the characteristic parity value storage with a predetermined parity value at a predetermined time-point in operation of the apparatus.

10. The method of claim 9, further comprising signalling compromised integrity when the characteristic parity value differs from the predetermined parity value.

11. The method of claim 9, wherein the predetermined time-point is immediately following a reset of the apparatus.

12. The method of claim 9, wherein the predetermined time-point is at a predetermined processing point during operation of the apparatus.

13. The method of claim 9, wherein the integrity verification comprises comparing an evolution sequence of the characteristic parity value stored in the characteristic parity value storage with a predetermined evolution sequence of the predetermined parity value.

14. The method of claim 9, wherein the integrity verification comprises determining whether the characteristic parity value stored in the characteristic parity value storage represents an impossible value,
wherein prior analysis of the apparatus has determined that the characteristic parity value cannot attain the impossible value during correct operation of the apparatus.

15. The method of claim 9, further comprising performing, prior to executing the software to perform integrity verification of the apparatus, a formal verification procedure to determine at least one of:
at least one possible value for the characteristic parity value; and/or
at least one impossible value for the characteristic parity value.

16. A system comprising:
the apparatus of claim 1, implemented in at least one packaged chip;
at least one system component; and
a board,
wherein the at least one packaged chip and the at least one system component are assembled on the board.

17. A chip-containing product comprising the system of claim 16, wherein the system is assembled on a further board with at least one other product component.

18. A non-transitory computer-readable medium storing computer-readable code for fabrication of an apparatus comprising:
data processing circuitry comprising data flip-flop parity circuitry, wherein the data flip-flop parity circuitry comprises:
prior parity calculation circuitry positioned prior to a data flip-flop group;
post parity calculation circuitry positioned following the data flip-flop group; and
parity comparison circuitry configured to compare respective outputs from the prior parity calculation circuitry and the post parity calculation circuitry, wherein the parity comparison circuitry is configured to signal a parity fault when the respective outputs differ;
parity value capturing circuitry configured to extract a parity value from a node in the data flip-flop parity circuitry, wherein the node is positioned before the parity comparison circuitry; and
characteristic parity value storage configured to store a characteristic parity value in dependence on the parity value extracted from the node by the parity value capturing circuitry.
